(19) United States
(12) Patent Application Publication
(10) Pub. No.: US 2014/0209818 A1
(43) Pub. Date: Jul. 31, 2014

(54) LITHOGRAPHY APPARATUS, LITHOGRAPHY METHOD, AND METHOD OF MANUFACTURING ARTICLE

(71) Applicant: CANON KABUSHIKI KAISHA, Tokyo (JP)

(72) Inventor: Satoru Oishi, Utsunomiya-shi (JP)

(73) Assignee: CANON KABUSHIKI KAISHA, Tokyo (JP)

(21) Appl. No.: 14/167,463

(22) Filed: Jan. 29, 2014

(30) Foreign Application Priority Data
Jan. 30, 2013 (JP) 2013-016134
Apr. 26, 2013 (JP) 2013-094636

(51) Int. Cl. G03F 7/20

(52) U.S. Cl. CPC G03F 7/70491
USPC 250/492.22

(57) ABSTRACT

A lithography apparatus measures a position of each sample shot, and obtains a measurement error with respect to each second shot region of the sample shot regions based on a position of each second shot region obtained by first regression calculation based on a measurement value of a position of each first shot region of the sample shot regions, and a measurement value of a position of each second shot region. After forming the pattern in at least one shot region, the apparatus measures a position of each of shot regions of the second shot regions in a partial area, and obtains positions of shot regions in the partial area by second regression calculation based on measurement values of the positions of shot regions in the partial area and the obtained measurement error.

### BACKGROUND OF THE INVENTION

1. Field of the Invention

The present invention relates to a lithography apparatus, lithography method, and method of manufacturing an article.

2. Description of the Related Art

In a drawing method of drawing a device pattern on a wafer by using an electron beam, the device pattern of the (n+1)th (n is a natural number) layer in a semiconductor wafer process is drawn on that of the nth layer. Before drawing the device pattern of the (n+1)th layer, alignment measurement is performed to measure the position of an alignment mark on a wafer in order to position (overlay) the nth and (n+1)th layers. When drawing a device pattern on a wafer by using an electron beam, the wafer thermally expands and deforms because heat applied to the wafer by electron beam exposure is high. The thermal deformation of the wafer sometimes decreases the overlay precision of the nth and (n+1)th layers.

To satisfy a demand for micropatterning of a semiconductor device, a high overlay precision is required. The overlay precision needs to be about ¼ of the minimum line width of a device pattern, for example, when the minimum line width is 32 nm, about 8 nm. To achieve such a high overlay precision, drawing needs to be performed by taking account of the thermal deformation of a wafer.

Japanese Patent Laid-Open No. 2000-228351 discloses a method of measuring the deformation or distortion of a wafer generated during an exposure process for each column (stripe), compensating for the thermal distortion of the wafer generated by the exposure process based on the measurement result, and then performing drawing.

Recently, semiconductor device manufacturing processes are becoming diversified. As a technique of planarizing a wafer in order to solve the problem of shortage of the depth of an exposure apparatus, techniques such as a CMP (Chemical Mechanical Polishing) process have been introduced. Along with this, an alignment mark on a wafer has an asymmetrical shape near the mark portion under the influence of the CMP process. FIG. 18 shows the section of an alignment mark on a wafer. In FIG. 18, the abscissa indicates the wafer radius (distance from the center of the wafer), and the ordinate indicates the asymmetry of the alignment mark. It is confirmed that the deformation (asymmetry) of the mark becomes larger as the wafer radius becomes larger, that is, toward the periphery of the wafer. If the alignment mark becomes asymmetrical, a resist applied on it also becomes asymmetrical, and the waveform of a signal corresponding to the alignment mark is deformed, generating an error in measurement of the mark position. The measurement error arising from the wafer process is called WIF (Wafer Induced Shift). In FIG. 18, the asymmetry of the mark becomes larger, that is, WIS becomes larger toward the wafer periphery. This phenomenon is called WIS nonlinearity.

These days, it is required to increase the overlay precision by reducing the measurement error of a mark position in consideration of WIS nonlinearity arising from a wafer process. There is a proposal to compensate for the thermal deformation of a wafer during drawing by an electron beam, as described in Japanese Patent Laid-Open No. 2000-228351. However, there is no proposal considering even WIS nonlinearity as mentioned above. This problem is not limited to a lithography apparatus using a charged particle beam, and is common to even a lithography apparatus of another scheme which needs to consider the thermal deformation of a wafer during pattern formation.

### SUMMARY OF THE INVENTION

The present invention provides, for example, a lithography apparatus advantageous in terms of overlay precision thereof. The present invention in its one aspect provide a lithography apparatus for forming a pattern sequentially in each of a plurality of shot regions on a substrate, the apparatus comprising: a measurement device configured to measure a position of a shot region on the substrate; and a controller configured to control the measurement device and obtain a position of each of the plurality of shot regions based on measurement by the measurement device, wherein the controller is configured to cause the measurement device to measure a position of each of a plurality of sample shot regions on the substrate, and to obtain, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, and to cause, after forming the pattern in at least one of the plurality of shot regions, the measurement device to measure a position of each of shot regions, of the plurality of second shot regions, in a partial area on the substrate where the pattern is to be formed, and to obtain positions of the shot regions in the partial area by second regression calculation based on measurement values of the positions of the shot regions in the partial area and the obtained measurement error.

Further features of the present invention will become apparent from the following description of exemplary embodiments with reference to the attached drawings.

### BRIEF DESCRIPTION OF THE DRAWINGS

FIG. 1 is a flowchart showing a drawing method in the first embodiment;

FIG. 2 is a schematic view showing the arrangement of a drawing apparatus;

FIG. 3 is a view for explaining an electron beam deflection operation;

FIG. 4 is a view for explaining the relationship between the arrangement of an electron beam and a column to be drawn;

FIG. 5 is a view showing an alignment optical system and control block according to the present invention;

FIG. 6 is a flowchart for explaining in detail creation of a WIS nonlinearity map;

FIG. 7 is a view showing a plurality of sample shot positions according to the present invention;

FIG. 8 is a view showing an example of the WIS nonlinearity map;

FIG. 9 is a view for explaining in detail calculation of a wafer thermal deformation component;

FIG. 10 is a view for explaining in detail calculation of a corrected grid;

FIG. 11 is a flowchart for explaining the second embodiment;

FIG. 12 is a table showing the calculation result of a magnification component for each column to be drawn according to the second embodiment;

FIG. 13 is a flowchart for explaining the third embodiment;

FIG. 14 is a flowchart for explaining the fourth embodiment;

FIG. 15 is a view showing sample shot positions for global alignment and a WIS nonlinearity map according to the fourth embodiment;

FIG. 16 is a flowchart for explaining the fifth embodiment;

FIG. 17 is a view for explaining sample shot positions according to the sixth embodiment;

FIG. 18 is a view showing WIS nonlinearity;

FIG. 19 is a view showing the concept of the eighth embodiment;

FIG. 20 is a flowchart for explaining the eighth embodiment;

FIG. 21 is a view for explaining calculation of a wafer thermal deformation component according to the ninth embodiment;

FIG. 22 is a view showing the concept of the ninth embodiment; and

FIG. 23 is a flowchart for explaining the ninth embodiment.

### DESCRIPTION OF THE EMBODIMENTS

### First Embodiment

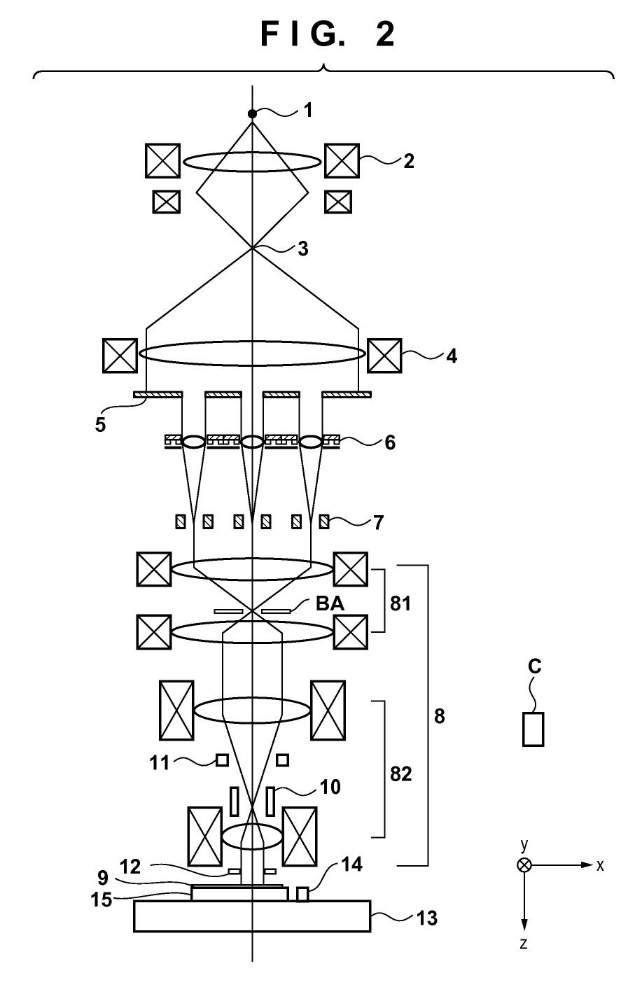

The present invention is applicable to a lithography apparatus which forms a pattern sequentially in respective shot regions on a substrate. The lithography apparatus can be a drawing apparatus which performs drawing on a substrate with a charged particle beam, or an exposure apparatus which exposes a substrate. The first embodiment will explain an example in which the lithography apparatus is a drawing apparatus using a plurality of electron beams. FIG. 2 is a schematic view showing the arrangement of the drawing apparatus using a plurality of electron beams. In FIG. 2, an electron beam emitted by an electron source 1 forms an image 3 of the electron source 1 via an optical system 2 which shapes an electron beam. The electron beam traveling from the image 3 is collimated into an almost parallel electron beam by a collimator lens 4. The almost parallel electron beam passes through an aperture array 5. The aperture array 5 has a plurality of apertures, and splits an electron beam into a plurality of electron beams. The plurality of electron beams split by the aperture array 5 form intermediate images of the image 3 via an electrostatic lens array 6 in which a plurality of electrostatic lenses are formed. A blanker array 7 in which a plurality of blankers serving as electrostatic deflectors are formed is arranged on the intermediate image plane.

An electron optical system (projection system) 8 formed from two symmetrical magnetic doublet lenses 81 and 82 is arranged downstream of the intermediate image plane. A plurality of intermediate images are projected on a wafer (substrate) 9. The electron optical system 8 has the Z-axis, and forms a plurality of electron beams into images on the surface of a substrate. The Z direction is a direction parallel to the axis of the electron optical system 8. An electron beam deflected by the blanker array 7 is cut off by a blanking aperture BA and does not irradiate the wafer 9. An electron beam not deflected by the blanker array 7 is not cut off by the blanking aperture BA and irradiates the substrate (wafer) 9. Deflectors 10 configured to displace a plurality of electron beams simultaneously to target drawing positions in the X and Y directions, and a focus coil 12 configured to simultaneously adjust the focuses of a plurality of electron beams are arranged in the lower doublet lens 82. A substrate stage (wafer stage) 13 holds the wafer 9 and is movable in the X and Y directions perpendicular to the axis of the electron optical system 8.

An electrostatic chuck 15 for fixing the wafer 9 is installed on the wafer stage 13. A detector 14 including a knife edge measures the shape of an electron beam at an irradiation surface position on the wafer 9. A stigmator 11 adjusts astigmatism of the electron optical system 8. The wafer stage 13 is moved by a step-and-repeat operation or step-and-scan operation. Electron beams are deflected at the same time as the movement of the wafer stage 13, drawing a pattern in a plurality of shot regions on the wafer 9 by the electron beams. A controller C controls the blanker array 7, deflector 10, focus coil 12, and wafer stage 13.

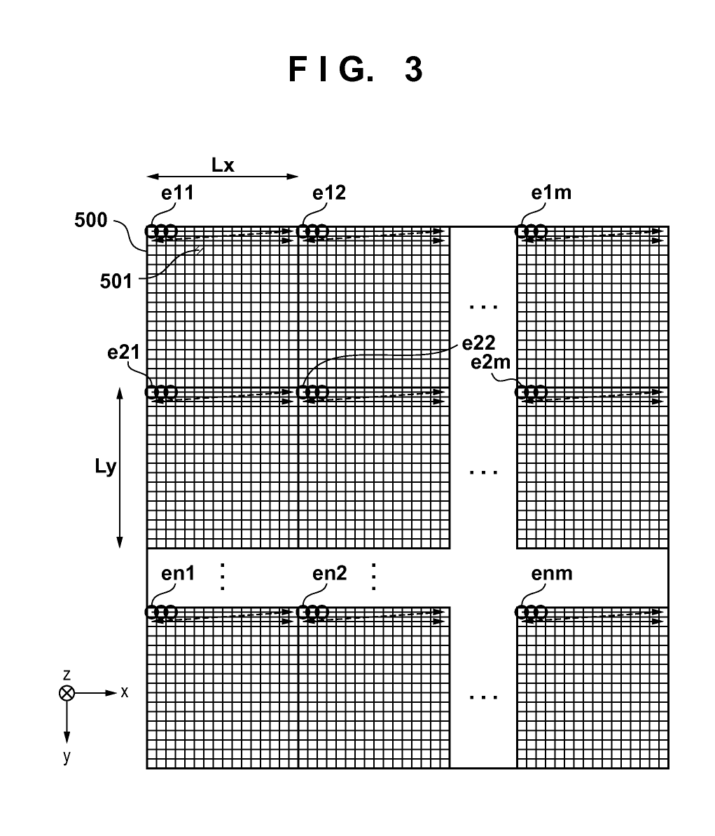

An electron beam deflection operation will be explained with reference to FIG. 3. The X direction is defined as a main deflection direction, and the Y direction is defined as a sub-deflection direction. m electron beams are arranged in the X direction, and n electron beams are arranged in the Y direction. The interval between adjacent electron beams is Lx in the main deflection direction and Ly in the sub-deflection direction. First, the controller C controls the X and Y deflectors 10 and the wafer stage 13 so that each electron beam irradiates an upper left drawing grid 501 of a drawing area 500 of the electron beam. At this time, the controller C performs drawing by driving the blanker array 7 and irradiating an electron beam for a predetermined time defined for each drawing grid 501 based on drawing data. The X deflector 10 sequentially moves the electron beam in the main deflection (X) direction. Along with this, respective drawing grids are drawn successively.

After the end of drawing on one row, the electron beam returns to the left end in the X direction, and drawing on the next row starts. At this time, the wafer stage 13 moves at a constant speed in the sub-deflection (Y) direction. The Y deflector 10 adjusts the deflection amount following the movement of the wafer stage 13. After the end of drawing on one row, the Y position of the electron beam returns to the initial position for drawing of the next row. Hence, the Y deflector 10 can perform deflection by the grid width of one row. By repeating this operation, drawing can be performed in the entire drawing area 500.

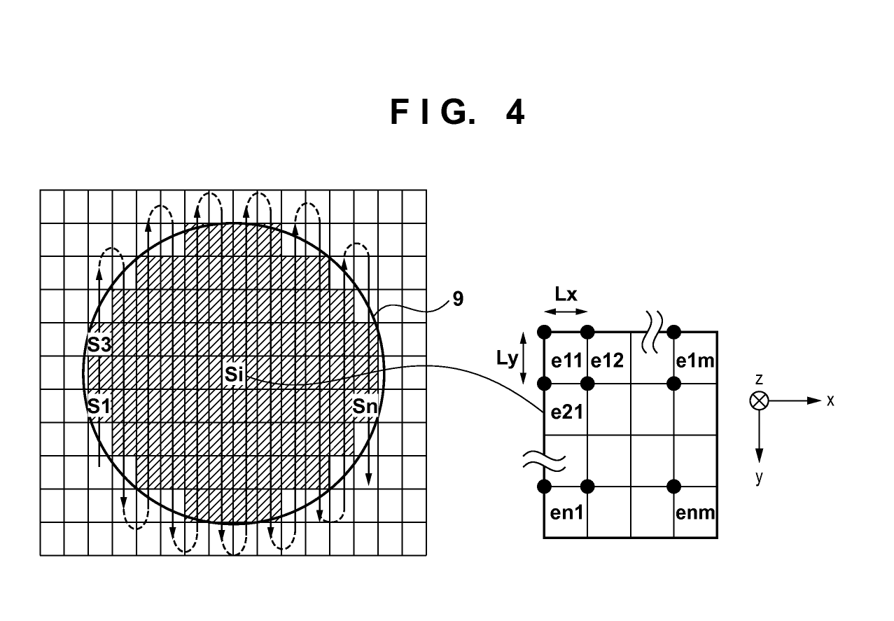

A column to be drawn in the embodiment will be described next. As shown in FIG. 4, a plurality of shot regions are formed in a matrix of rows and columns, and a pattern is drawn continuously in a plurality of shot regions for each column. In FIG. 4, the X interval between adjacent electron beams is a main deflection width Lx, and the Y interval is a sub-deflection width Ly. The X length (for example, 26 mm) in a shot region Si is designed to coincide with the X length (m×Lx) of the drawing area 500 in FIG. 3. By deflecting, in the main deflection direction, m electron beams in the X direction, a region having the X length of the shot region Si can be drawn. When movement of the wafer stage 13 in the Y direction and deflection in the Y direction are further combined, the pattern region (26 mm×33 mm) of the shot region Si can be drawn. By repeating this drawing operation from shot regions S1 to S3 in FIG. 4 in a direction indicated by an arrow, drawing of the first column of the wafer 9 can be ended. The controller C moves the wafer stage 13 step by step sequentially by the width of the shot region in the X direction. Then, the Y scan direction is reversed to perform pattern drawing in shot regions of the next column. By repeating this operation, the pattern is drawn in shot regions on the entire wafer surface.

A method of measuring the height of the wafer 9 in the axial (Z-axis) direction of the electron optical system 8 will be explained. In an electron beam drawing apparatus, the drawing environment needs to be a vacuum in order to prevent attenuation of an electron beam for drawing. When the Z height of the wafer 9 is measured in the drawing apparatus, it needs to be measured in vacuum. As the method of measuring the Z height of the wafer 9, triangulation using light (oblique incidence+image shift method), or a method using a capacitance sensor or the like is conceivable. However, the measurement method is not particularly limited as long as it can be performed in vacuum.

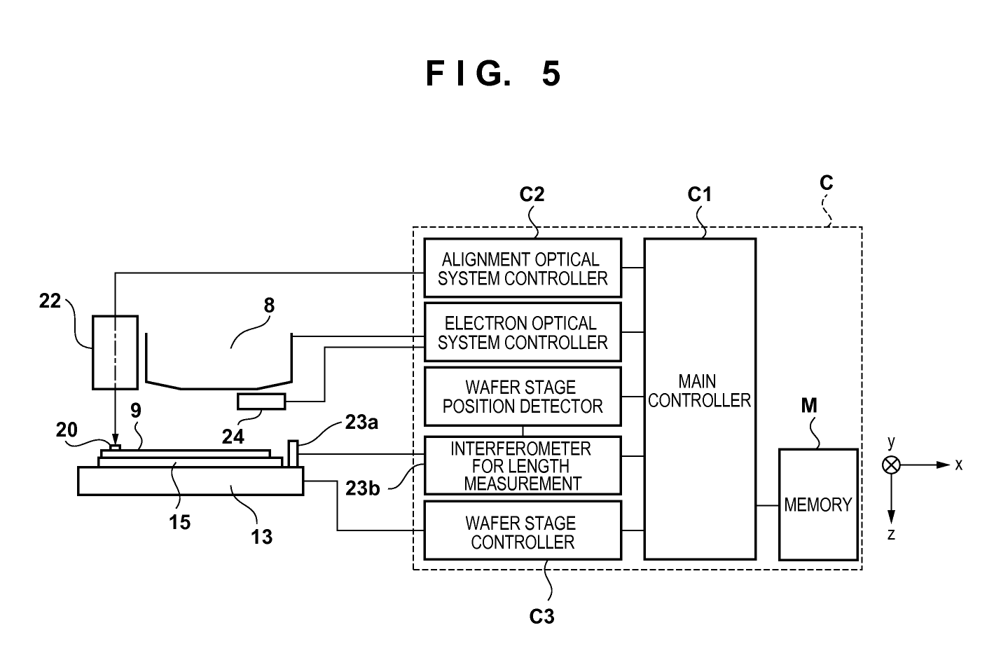

Next, positioning, that is, alignment of the wafer 9 will be described. While deflecting an electron beam, a pattern is drawn on the wafer 9 as follows by using an off-axis alignment scope 22. The alignment scope 22 is a measurement device capable of measuring the position of each of a plurality of shot regions. In FIG. 5, alignment marks 20 are formed in a plurality of shot regions on the wafer 9. The off-axis alignment scope 22 detects the image signal of the alignment mark 20, and an alignment scope controller C2 processes the detected image signal to measure the position of the alignment mark 20. At this time, the position of the wafer stage 13 that has been measured by an interferometer 23b including a mirror 23a installed on the wafer stage 13 is stored in a memory M via a main controller C1. The interferometer 23b measures the position of the wafer stage 13 in the X and Y directions perpendicular to the Z direction of the wafer stage 13 and the axis of the electron optical system 8.

A wafer stage controller C3 moves a plurality of sample shot regions selected from a plurality of shot regions on the wafer 9. The alignment scope 22 measures the positions of the alignment marks 20 in the selected sample shot regions. The alignment scope controller C2 performs regression calculation based on alignment measurement values in the plurality of sample shot regions, obtaining the coefficients of a liner regression expression (regression expression concerning so-called global alignment) in regard to, for example, position coordinates represented in equation (1):

$$( \begin{matrix}{x}^{′} \\ {y}^{′}\end{matrix} ) = ( \begin{matrix}Sx \\ Sy\end{matrix} ) + ( \begin{matrix}mx cos θ x & - my sin θ y \\ mx sin θ x & my cos θ y\end{matrix} ) ( \begin{matrix}x \\ y\end{matrix} ) \qquad ( 1 )$$

where (x, y) are the position coordinates of a shot region before correction, (x′, y′) are the position coordinates of the shot region after correction, Sx and Sy are shift components (coefficients concerning shift), mx and my are magnification components (coefficients concerning magnification), and θx and θy are rotation components (coefficients concerning rotation).

In general, x′ and y′ are given by linear expressions of x and y according to equations (2):

x′=a₁x+b₁y+Sx

y′=a₂x+b₂y+Sy (2)

The main controller C1 positions a shot region to undergo pattern formation to the corrected position (x′, y′) obtained by equation (1) or equations (2), and draws a pattern.

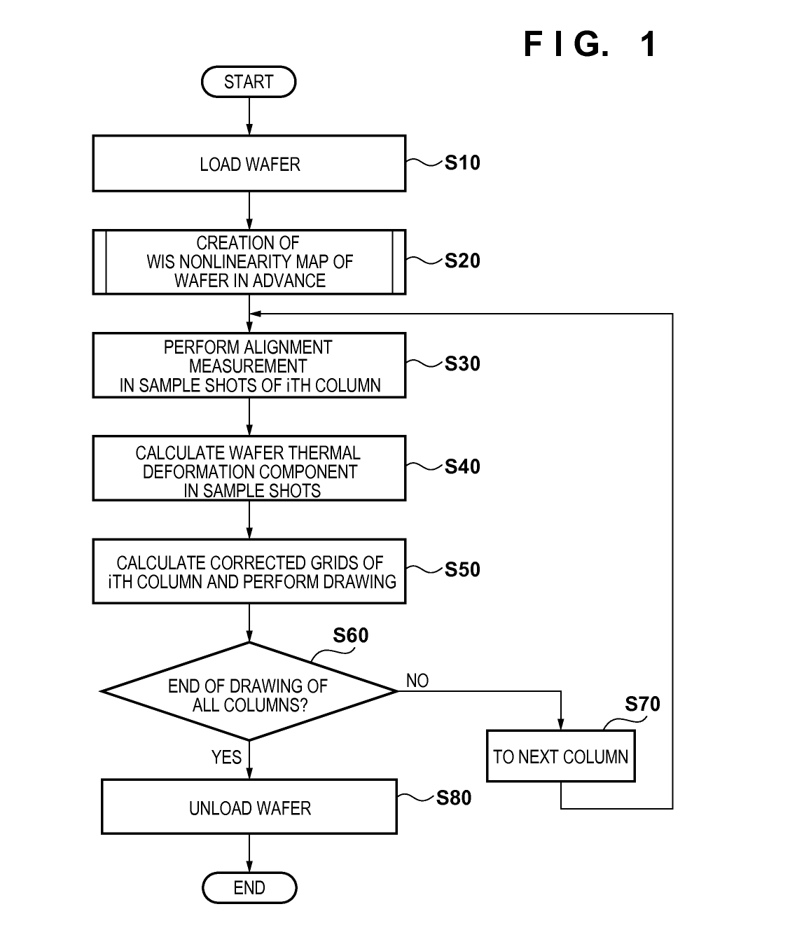

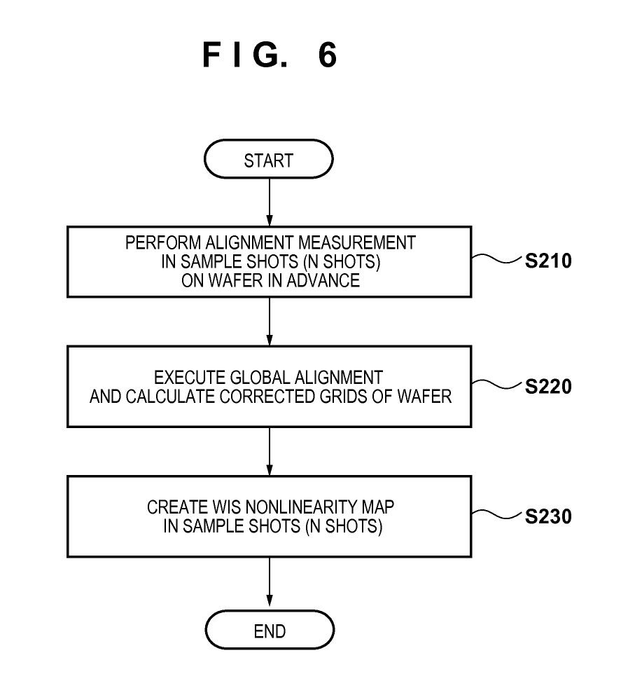

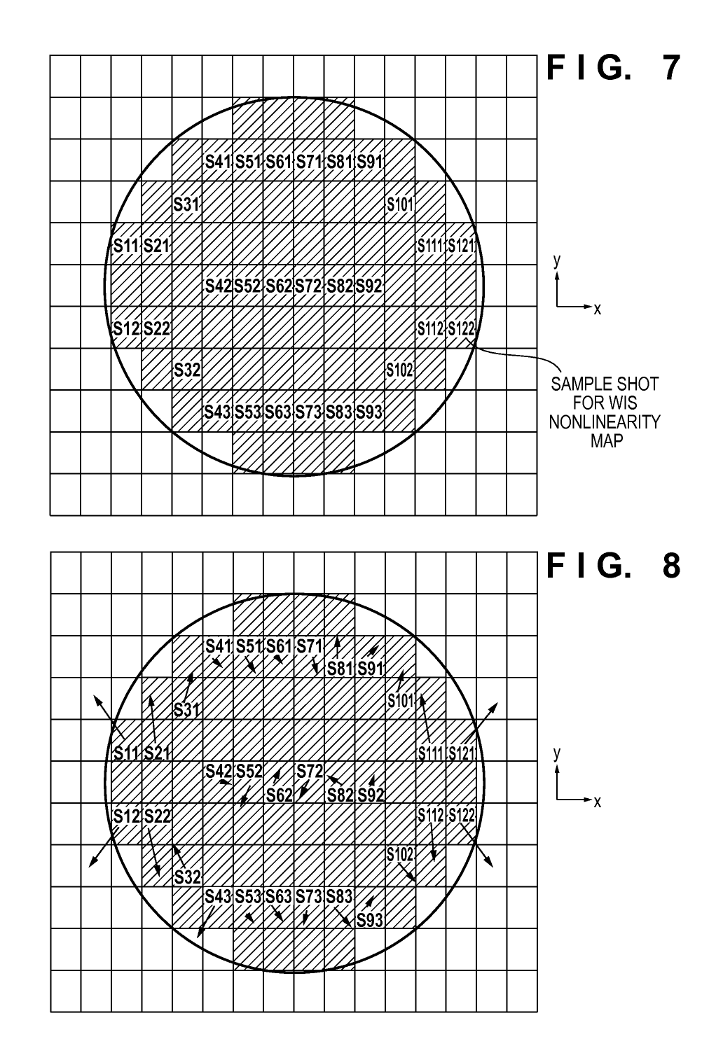

FIG. 1 is a flowchart showing a drawing sequence in the first embodiment. In step S10, the wafer 9 is transported onto the wafer stage 13. In step S20, the nonlinearity map of WIS serving as a measurement error arising from an executed process is created in advance for the wafer 9 before forming a pattern in a plurality of shot regions. The creation of the WIS nonlinearity map in step S20 will be described in detail with reference to FIG. 6. In step S210, the main controller C1 performs in advance alignment measurement to obtain the first measurement values and the above-mentioned coefficients in a plurality of first shot regions (first sample shot regions) among a plurality of sample shot regions by using the off-axis alignment scope 22. FIG. 7 shows an example of the first sample shot regions selected from a plurality of shot regions formed in a matrix. According to the embodiment, in FIG. 7, a region in which shot regions are aligned in the Y direction will be called a column, and columns will be called the first column, second column, . . . sequentially in the positive X direction. As the shot numbers of the first sample shot regions shown in FIG. 7, serial numbers are added to column numbers for respective columns. For example, S52 indicates the second sample shot region on the fifth column. Referring back to FIG. 6, in step S220, the main controller C1 executes global alignment measurement to perform the first regression expression and obtain the second measurement values by using a plurality of second shot regions (second sample shot regions) among the first sample shot regions. In the first embodiment, the plurality of first sample shot regions and the plurality of second sample shot regions include common sample shot regions. In this case, for common sample shot regions, measurement need not be executed repetitively (when all the second sample shot regions are included in the first sample shot regions, no additional measurement need be performed).

In step S230, the main controller C1 creates a WIS nonlinearity map in sample shot regions of each ith column. FIG. 8 shows an example of the WIS nonlinearity map. The measurement values in a plurality of sample shot regions in step S220 include actual distortion (linear component) of the wafer itself and a measurement error (WIS nonlinear component) arising from a wafer process. In step S210, a plurality of sample shot regions are selected isotropically and symmetrically with respect to the wafer center. Thus, the influence of the WIS nonlinear component is reduced in the linear component of the wafer distortion obtained by regression from these measurement values. In each sample shot region, the main controller C1 obtains the difference between a grid array (shot region array: position of a shot region) calculated from the linear component of the wafer 9 obtained in step S210, and the second measurement value obtained in step S220, and defines it as a WIS nonlinear component in step S230. FIG. 8 shows that the WIS nonlinear component becomes larger toward the periphery of the wafer 9. Note that the main controller C1 creates a database of the WIS nonlinearity map measured in step S230, and stores it in the memory M. The creation of the WIS nonlinearity map in step S20 has been described.

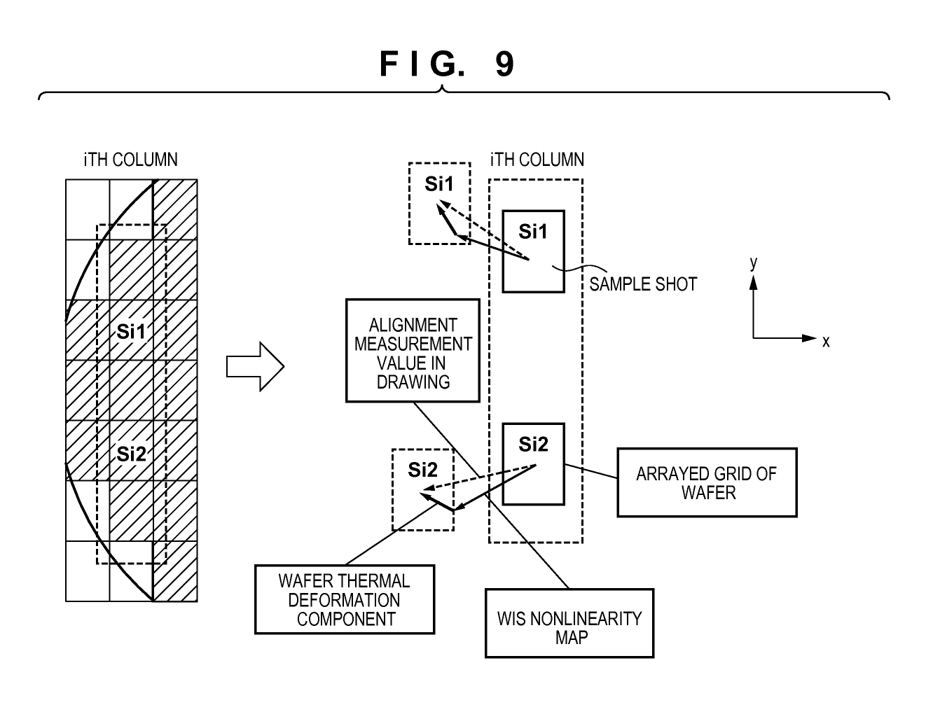

Referring back to FIG. 1, in step S30, the main controller C1 forms a pattern in at least some shot regions, and then performs alignment measurement in sample shot regions of a column of a partial area to undergo pattern formation. In step S40, the main controller C1 calculates a wafer thermal deformation component in the sample shot regions. Step S40 will be explained in detail with reference to FIG. 9. Si1 and Si2 are two sample shot regions of the ith column. Each alignment measurement value includes a WIS nonlinear component (measurement error) and a wafer thermal deformation component generated upon drawing on the preceding column (i−1th column). Since the WIS nonlinear component has been calculated in step S20, the main controller C1 subtracts the WIS nonlinear component from the alignment measurement value in each sample shot region, and estimates a wafer thermal deformation component in the sample shot region in step S40.

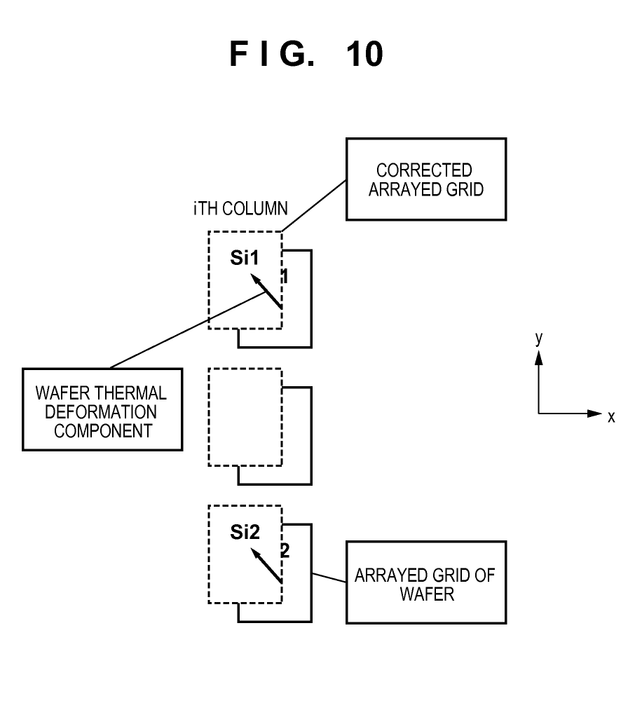

In step S50, the main controller C1 obtains an array of corrected grids (arrayed shot regions) of the ith column by correcting the grid array of the ith column by using only the wafer thermal deformation component. The main controller C1 draws a pattern based on the obtained corrected grid array. FIG. 10 shows wafer thermal deformation components indicated by arrows in the sample shot regions Si1 and Si2 of the ith column. A corrected grid calculation equation is given by equation (3):

$$( \begin{matrix}{X}^{′} \\ {Y}^{′}\end{matrix} ) = ( \begin{matrix}{S}_{X} \\ {S}_{Y}\end{matrix} ) + ( \begin{matrix}m cos θ & - m sin θ \\ m sin θ & m cos θ\end{matrix} ) ( \begin{matrix}X \\ Y\end{matrix} ) \qquad ( 3 )$$

where X and Y are the coordinates x′ and y′ of an arrayed grid (arrayed shot region) on the wafer that have been calculated in step S210, X′ and Y′ are the coordinates of a grid corrected based on the wafer thermal deformation component using equation (3), S_{X} and S_{Y} are the X and Y shift components, m is the magnification component, and θ is the rotation component. In the embodiment, as the sample shot regions in FIG. 7, two or more shot regions are set for each column to be drawn, in order to perform the correction calculation of equation (3) for each column to be drawn.

In step S60, the main controller C1 determines whether the pattern has been drawn on all the columns. If an undrawn column remains, the main controller C1 moves the stage to the next column in step S70 and repeats alignment measurement in sample shot regions of the next column in step S30. After the pattern is drawn on all the columns, the wafer 9 on which the pattern has been drawn is unloaded in step S80, ending the drawing sequence. The drawing method according to the present invention has been described.

### Second Embodiment

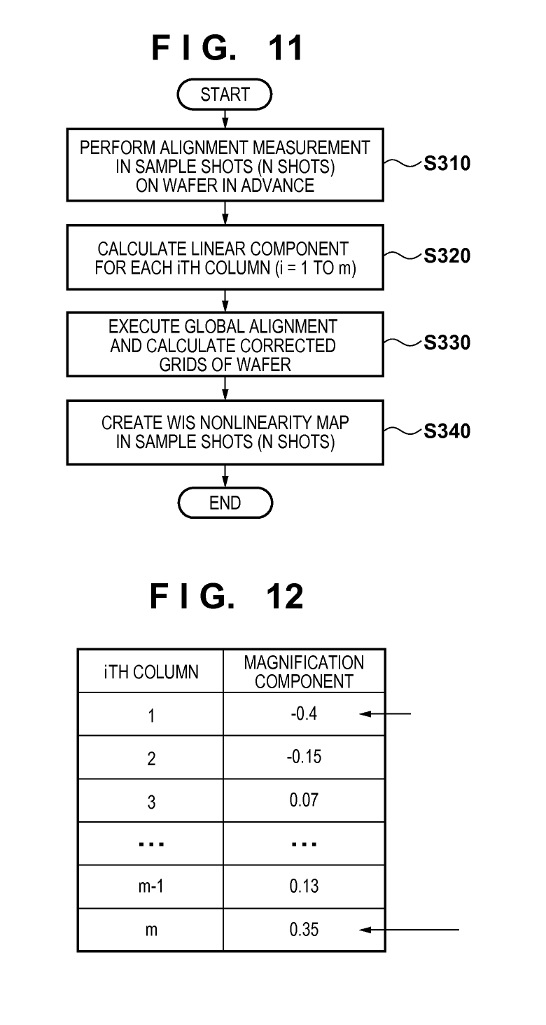

The second embodiment has a feature in which, when obtaining a grid array on a wafer in step S220 of FIG. 6 in creation of a WIS nonlinearity map, the linear component of each column is calculated to obtain the grid array on the wafer based on the result. FIG. 11 is a flowchart for explaining the second embodiment. A main controller C1 performs alignment measurement in sample shot regions in step S310, similar to step S210, and calculates a linear component for each column to be drawn in step S320. FIG. 12 is a table showing an example of the calculation result of the linear component (magnification component) for each column to be drawn (i=1 to m). In step S330, the main controller C1 executes global alignment measurement to calculate the linear component of a wafer 9. At this time, the main controller C1 excludes, from calculation of the grid array of the wafer, sample shot regions of a column on which the value of the linear component is larger than a tolerance. That is, the main controller C1 calculates a linear component by using only data of sample shot regions of a column on which the regression error of the first regression falls within the tolerance. In FIG. 12, for example, when the tolerance of the magnification is set to be equal to or smaller than 0.3 ppm, the main controller C1 calculates arrayed grids on the wafer 9 according to global alignment (equation (1)) based on measurement values in sample shot regions excluding the first and mth columns indicated by arrows. In step S340, the main controller C1 creates a WIS nonlinearity map in each sample shot region by using, as a WIS nonlinear component, the difference between the measurement value in the sample shot region and the arrayed grid.

### Third Embodiment

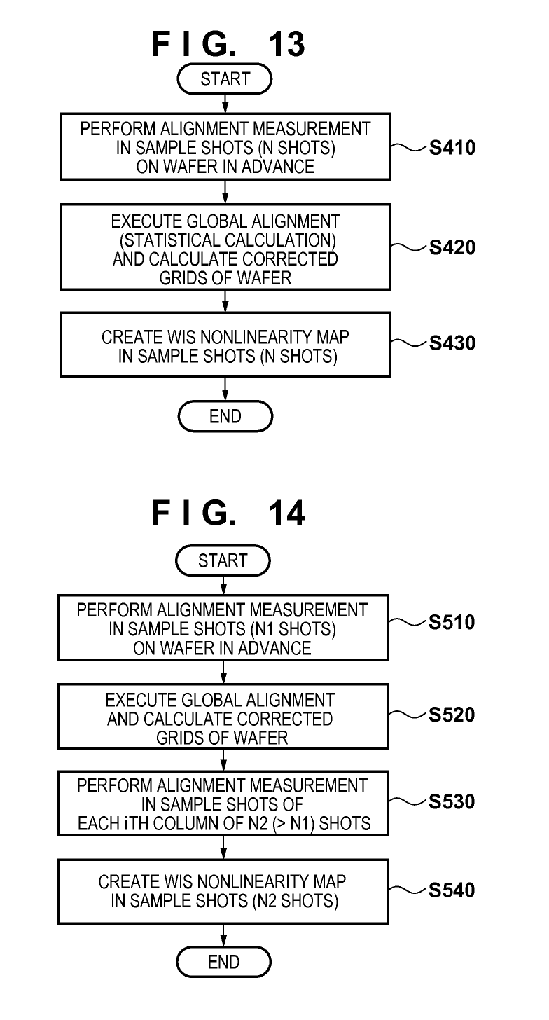

The third embodiment is different from the second embodiment in the selection criterion of sample shots used to create the WIS nonlinearity map of a wafer 9. The third embodiment will be described in detail below with reference to FIG. 13. Here, so-called advanced global alignment (AGA) measurement is performed to exclude, as an abnormal value (abnormal region), a sample shot region having a large residual (error) from a wafer grid in global alignment measurement. In step S410, a main controller C1 performs in advance alignment measurement in a plurality of sample shot regions (N shots) on the wafer 9. In step S420, the main controller C1 obtains the coefficients of equation (1) concerning global alignment, excluding abnormal values from the measurement values of the sample shot regions, and obtains a grid array (positions of shot regions) based on the wafer linear component. In step S430, the main controller C1 sets, as WIS nonlinear components, the differences between the grid array and measurement values in respective sample shot regions, and maps the WIS nonlinear components in sample shot regions of each ith column.

### Fourth Embodiment

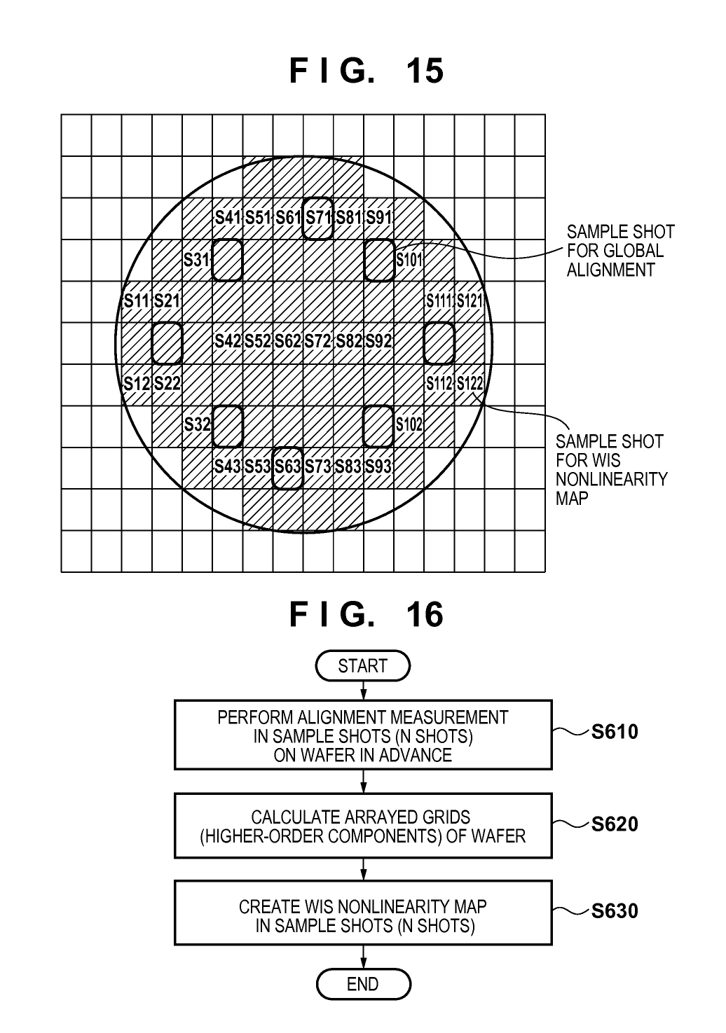

In the fourth embodiment, sample shot regions used when calculating a grid array on a wafer 9 in global alignment measurement are different from sample shot regions used to create a WIS nonlinearity map. The fourth embodiment will be described with reference to FIG. 14. In step S510, when calculating a grid array on the wafer 9, a main controller C1 selects N1 sample shot regions indicated by black frames in FIG. 15, and performs alignment measurement. In step S520, the main controller C1 calculates a grid array on the wafer 9 based on global alignment measurement in the N1 sample shot regions. In step S530, the main controller C1 performs alignment measurement in N2 sample shot regions larger in number than N1, for example, in sample shot regions S11 to S122 shown in FIG. 15. In step S540, the main controller C1 calculates and maps WIS nonlinear components of each ith column based on the grid array (positions of shot regions) obtained in step S520.

In the fourth embodiment, sample shot regions differ between global alignment measurement and measurement for creating a WIS nonlinearity map. In addition, the arrangement of an alignment measurement device (for example, the arrangement of an alignment measurement optical system) may differ between these measurements. For example, a measurement device in which position measurement takes time but the influence of WIS is reduced can be used in step S510, and a measurement device capable of quick position measurement though the influence of WIS nonlinearity is not small can be used in step S530.

### Fifth Embodiment

The fifth embodiment has a feature in which two-dimensional arrayed grids serving as a basis for calculating a WIS nonlinearity map are based not only on the X and Y first-order components (linear components or first-order terms), but also on higher-order components. The fifth embodiment copes with not linear but nonlinear deformation of the grid array of a wafer 9 by heat treatment or the like in a semiconductor process.

The fifth embodiment will be explained with reference to FIG. 16. A main controller C1 performs alignment measurement in a plurality of sample shot regions on the wafer 9 in step S610, and calculates the grid array of the wafer 9, including the higher-order terms of the X- and Y-coordinates in step S620. In step S630, the main controller C1 maps, as WIS nonlinear components, the differences between grids (positions of sample shot regions) calculated (regressed) in step S620 and the measurement values of the sample shot regions.

The inclusion of the higher-order terms of the X- and Y-coordinates means that, for example, equations (2) include higher-order terms such as X², XY, Y³, X³, X²Y, XY², Y³, . . . in addition to the first-order terms of equations (2). For example, assuming higher-order components up to third-order components, the grid array is given by equations (4):

x′=a₀+a₁x+a₂y+a₃x²+a₄xy+a₅y²+a₆x³+a₇x²y+a₈xy²+a₉y³

y′=b₀+b₁x+b₂y+b₃x²+b₄xy+b₅y²+b₆x³+b₇x²y+b₈xy²+b₉y³ (4)

### Sixth Embodiment

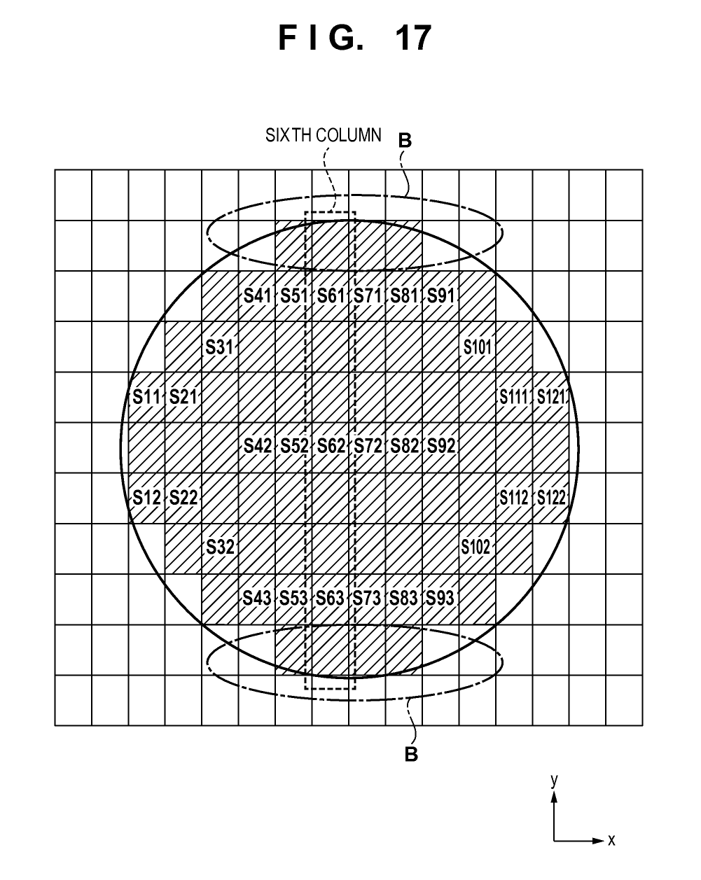

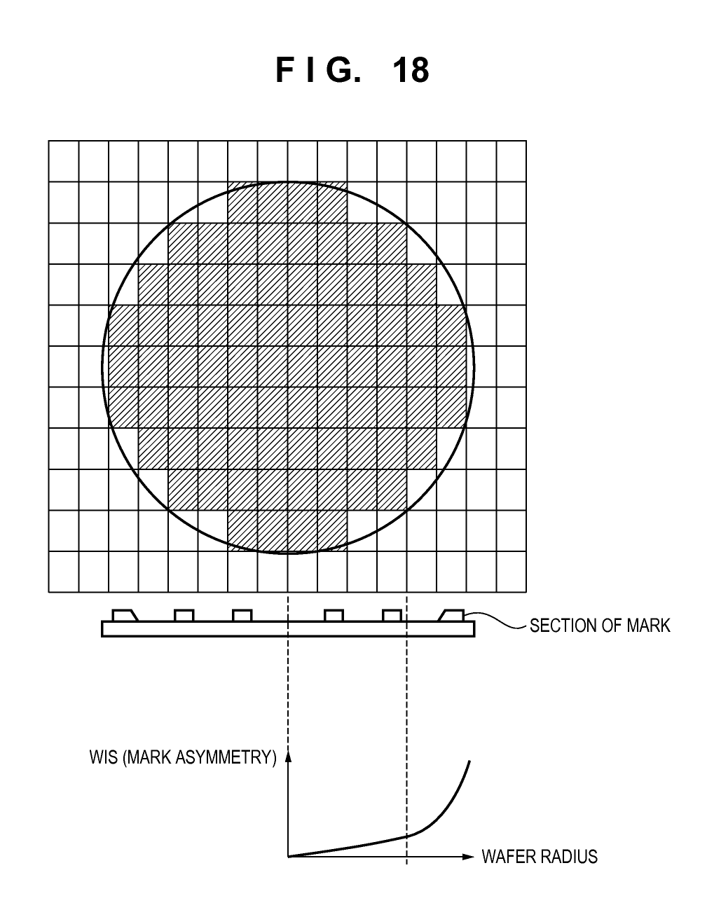

The sixth embodiment has a feature in which, when performing alignment measurement in a plurality of sample shot regions on a wafer 9 in step S210, sample shot regions of each column do not include sample shot regions positioned at the periphery of the wafer 9. That is, sample shot regions for global alignment are shot regions arranged so that other shot regions exist outside them. In FIG. 17, a region B is a region which exists at the periphery of the wafer 9 and is greatly influenced by WIS nonlinearity. For this reason, in the sixth embodiment, shot regions at the periphery are excluded when calculating a two-dimensional grid array for calculating a WIS nonlinearity map. For example, as sample shot regions on the sixth column, three shot regions S61, S62, and S63 excluding a shot region in the region B are selected.

### Seventh Embodiment

In the seventh embodiment, a corrected grid array of the ith column is calculated in step S50 of FIG. 1 by using not only sample shot regions of the ith column but sample shot regions of the (i−1)th and (i+1)th preceding and succeeding columns. More specifically, there are the following two methods.

In the first method, measurement of sample shot regions of the (i−1)th preceding column or (i+1)th succeeding column is performed together with measurement of sample shot regions of the ith column. Measurement of sample shot regions of the (i−1)th and (i+1)th columns may be performed together with measurement of sample shot regions of the ith column.

The second method uses even the result of alignment measurement of the (i−1)th column that has been executed before drawing of the (i−1)th preceding column. In the second method, if a wafer thermal deformation component calculated in measurement of sample shot regions of a preceding column is held till drawing of the ith column, alignment measurement of the preceding column need not be performed again, which is superior to the first method in terms of throughput.

A main controller C1 calculates a corrected grid array by using the alignment measurement results of sample shot regions of the ith column, and those of sample shot regions of preceding and succeeding columns. In the seventh embodiment, calculation is performed using even sample shot regions of columns different in the X position, so the corrected grid array can be calculated at a higher degree of freedom of compensation for the magnification component and rotation component upon thermal deformation, compared to a case in which sample shot regions of only the ith column are used as shown in FIG. 9. Letting mₓ and m_{y} be magnification components, and θ_{X} and θ_{Y} be rotation components, the corrected grid array can be calculated based on equation (5), which is advantageous for overlay precision:

$$( \begin{matrix}{X}^{′} \\ {Y}^{′}\end{matrix} ) = ( \begin{matrix}{S}_{X} \\ {S}_{Y}\end{matrix} ) + ( \begin{matrix}{m}_{x} cos {θ}_{x} & - {m }_{Y} sin {θ}_{Y} \\ {m}_{x} sin {θ}_{x} & {m }_{Y} cos {θ}_{Y}\end{matrix} ) ( \begin{matrix}X \\ Y\end{matrix} ) \qquad ( 5 )$$

### Eighth Embodiment

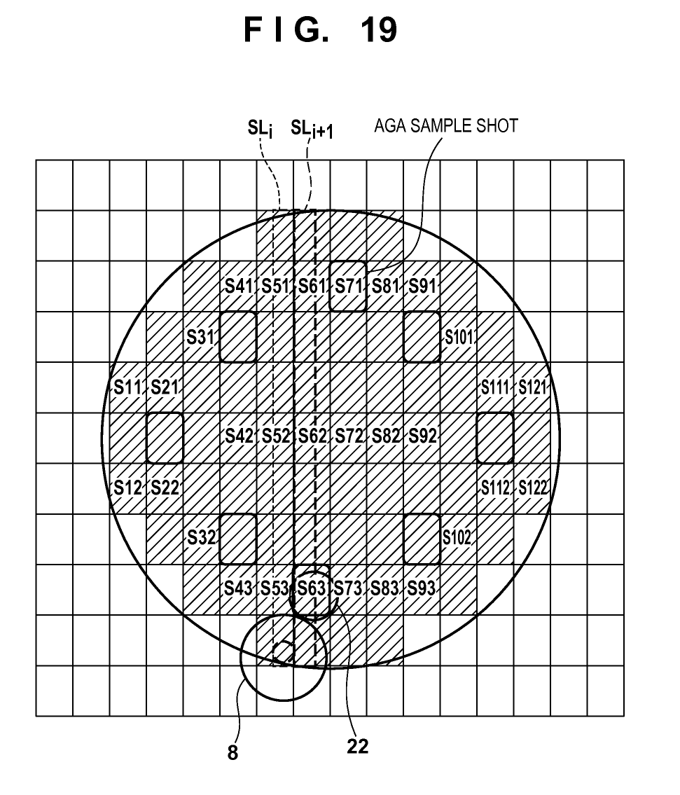

The first to seventh embodiments have explained an aspect in which drawing is performed for each shot of a wafer in the drawing area 500. In the eighth embodiment, a drawing apparatus performs drawing for each divided region (slit) in which an X length obtained by dividing shot regions of one column by a dividing line in the column direction is smaller than the width (26 mm) of the shot region. FIG. 19 is a conceptual view showing the eighth embodiment. In FIG. 19, sample shots (AGA sample shots) used for global alignment are eight shots, and the drawing apparatus performs drawing in a next slit SLᵢ₊₁ after drawing in a slit SLᵢ. This slit drawing is premised on that drawing is performed from one end to the other end of a wafer 9. In the eighth embodiment, it is advantageous in throughput to measure a mark for which the driving amount of a wafer stage 13 is small, after a drawing area 500 reaches the upper or lower end of the wafer 9. Hence, after drawing of the slit SLᵢ, an alignment scope 22 measures the alignment marks of two shots S71 and S63 nearest the next slit SLᵢ₊₁ among AGA sample shots. A main controller C1 suffices to consider wafer thermal deformation components and reflect them on drawing based on a WIS nonlinearity map obtained in advance at the positions of the two sample shots S71 and S63, and the measurement values of the shots S71 and S63 after drawing of the slit SLᵢ.

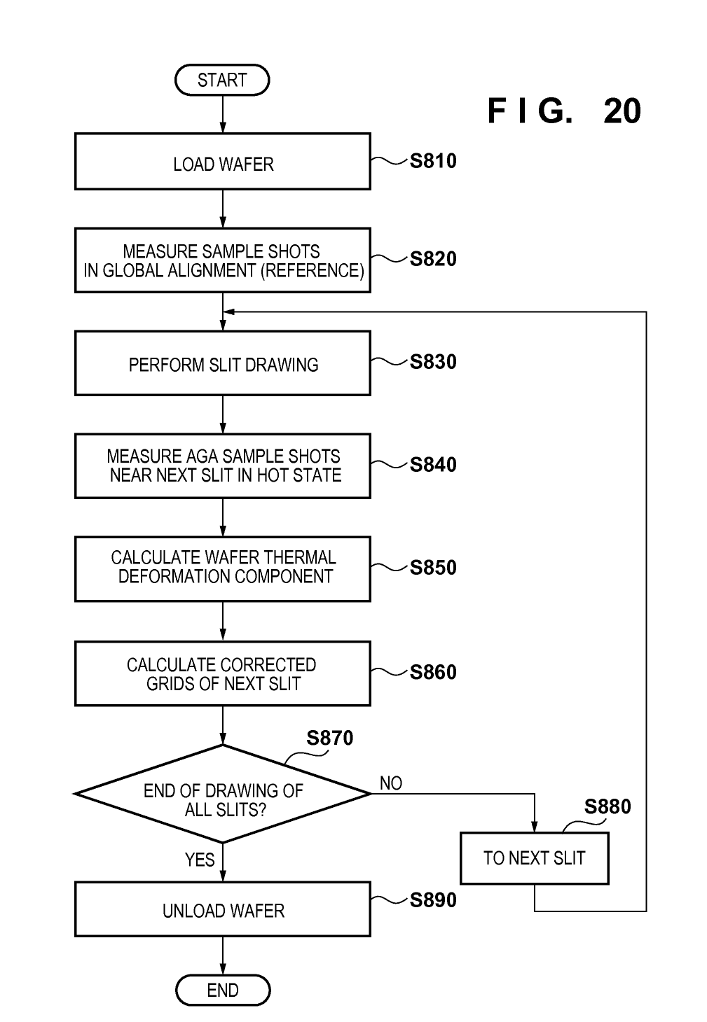

The eighth embodiment will be explained with reference to the flowchart of FIG. 20. In step S810, a main controller C1 transports the wafer 9 onto the wafer stage 13. In step S820, the main controller C1 performs alignment measurement in AGA sample shots by using the alignment scope 22 in a cool state in which the wafer 9 has been transported on the wafer stage 13. At this time, the main controller C1 calculates the reference arrayed grids of the wafer 9 and creates a WIS nonlinearity map in the AGA sample shots. The main controller C1 forms the pattern of a slit SLᵢ in step S830 and performs in step S840 alignment measurement in the AGA sample shots S71 and S63 near a slit SLᵢ₊₁ to undergo the next pattern formation in a hot state after drawing of the slit. In step S850, the main controller C1 calculates wafer thermal deformation components in the AGA sample shots S71 and S63 from the WIS nonlinear components and WIS nonlinear components in step S820.

In step S860, the main controller C1 calculates corrected grids of the next slit SLᵢ₊₁ by using the wafer thermal deformation components calculated in step S850. This will be explained with reference to FIG. 19. The main controller C1 calculates corrected grids including shift, magnification, and rotation components in accordance with equation (5) from the wafer thermal deformation components in the target AGA sample shots S71 and S63 near SLᵢ₊₁, and the arrayed grids of the wafer 9 in the cool state. As a matter of course, when target AGA sample shots have the same X position, corrected grids are calculated using equation (1). The main controller C1 repeats slit drawing while performing positioning of the next slit SLᵢ₊₁ in step S880 till the end of drawing of all slits in step S870.

When drawing is repeated from one end to the other end of a wafer, as in the eighth embodiment, a wafer thermal deformation is measured using AGA sample shots near the end. Compared to the fourth embodiment shown in FIG. 14, the number N2 of sample shots for measuring a wafer thermal deformation can be decreased to N1, movement of the wafer stage 13 necessary for measurement can be minimized, and improvement of the throughput can thus be expected.

### Ninth Embodiment

In the first to eighth embodiments, there is one alignment scope (measurement device) for measuring the thermal deformation component of the wafer 9. In the ninth embodiment, there are a plurality of measurement devices for alignment. Particularly in the ninth embodiment, a measurement device (first measurement device) for measuring the arrayed grids of a wafer 9 by global alignment before drawing on a wafer, and a measurement device (second measurement device) for calculating a wafer thermal deformation component after the start of slit drawing are different.

The first measurement device used for global alignment has a high precision (first precision) at which aberration of the optical system and the like are suppressed in order to reduce the influence of a measurement error arising from the interaction between a wafer process error WIS and an apparatus error TIS. In contrast, the second measurement device which performs alignment measurement in AGA sample shots upon drawing of a slit after the start of drawing on a wafer has the second precision lower than the first precision because the specification of the apparatus error TIS of the optical system is not so strict.

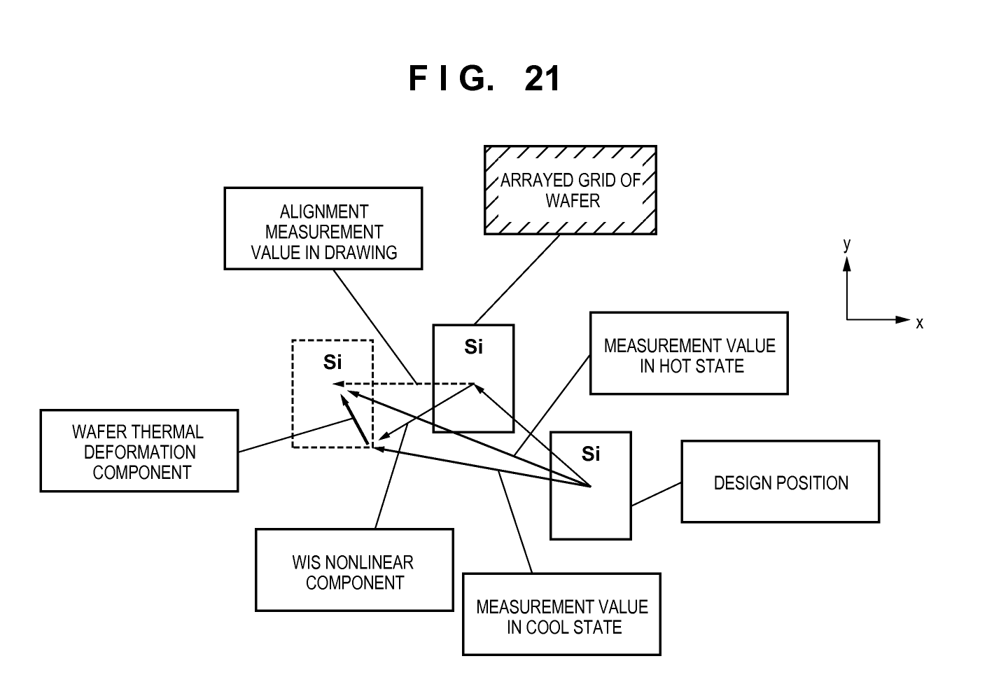

FIG. 21 shows an example of calculation of a wafer thermal deformation component in the ninth embodiment. In the first to eighth embodiments, a single alignment scope is used for both global alignment and the wafer thermal deformation component. In the ninth embodiment, the first measurement device for global alignment and the second measurement device for the wafer thermal deformation component are separately arranged, as described above. In the ninth embodiment, an alignment measurement value by the first measurement device for global alignment is not used to calculate the thermal deformation component of the wafer 9. Instead, the difference between an alignment measurement value in the cool state before drawing on the wafer 9 and an alignment measurement value in the hot state in drawing is calculated. This difference serves as the wafer thermal deformation component of the shot. That is, no WIS nonlinearity map need be managed to calculate a wafer thermal deformation component in the ninth embodiment. Therefore, a low-cost alignment scope (second measurement device) may be used, in which a large WIS is generated owing to the interaction between TIS and WIS.

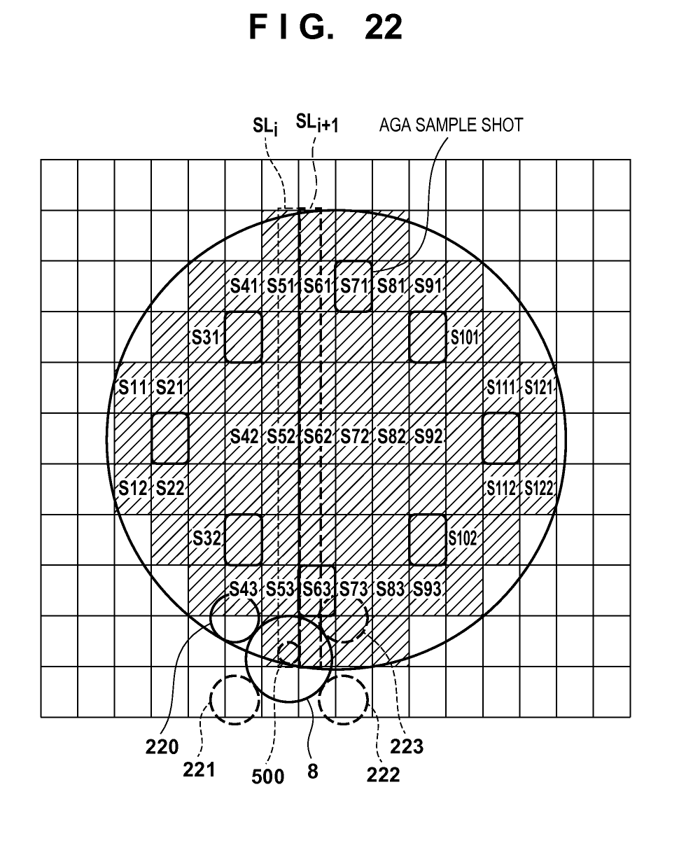

The ninth embodiment suffices to use a high-precision alignment scope (first measurement device) for calculation of the arrayed grids of a wafer by global alignment, and a low-precision low-cost alignment scope (second measurement device) for calculation of a wafer thermal deformation component. FIG. 22 is a conceptual view showing the ninth embodiment. A plurality of second measurement devices 221 to 223 are arranged in addition to a first measurement device 220. This arrangement has effects of shortening the alignment measurement time and increasing the throughput. For example, when a drawing area 500 is located at the lower end of the wafer 9 and an AGA sample shot is located at an upper right portion (S63 position in FIG. 22) with respect to the drawing area, measurement is performed using the second measurement device 223. When the drawing area is located at the upper end of the wafer 9 and a sample shot is located at a lower right portion with respect to the drawing area, if measurement is performed using the second measurement device 222, the throughput can be increased.

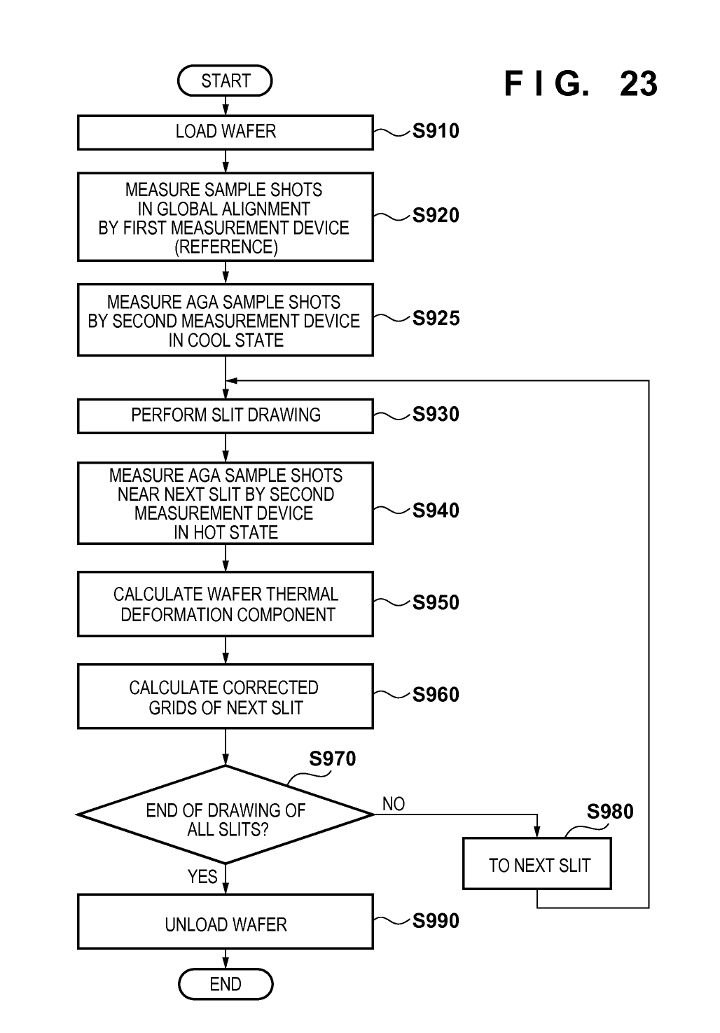

Next, the ninth embodiment will be explained with reference to the flowchart of FIG. 23. In step S910, a main controller C1 transports the wafer 9 onto a wafer stage 13. In step S920, the main controller C1 performs alignment measurement in AGA sample shots by using the high-precision first measurement device 220 in which the apparatus error TIS of the optical system is suppressed. At this time, the main controller C1 calculates the reference arrayed grids of the wafer 9 free from the influence of the wafer process error WIS. In step S925, the main controller C1 similarly performs measurement in the cool state in the AGA sample shots by using the second measurement devices 221 to 223.

The main controller C1 forms the pattern of a slit SLᵢ in step S930, and performs alignment measurement in AGA sample shots near the slit SLᵢ₊₁ to undergo the next pattern formation by using the second measurement devices 221 to 223 in the hot state in step S940. In step S950, the main controller C1 calculates the difference between the two types of measurement values, that is, the measurement value of each of these AGA sample shot in the hot state in step S940 and its measurement value in the cool state in step S925 by using the second measurement devices 221 to 223. The main controller C1 sets the calculated difference as a wafer thermal deformation component. In step S960, the main controller C1 calculates corrected grids of the next slit SLᵢ₊₁ by using the reference arrayed grids of the wafer 9 obtained by global alignment in step S920, and the wafer thermal deformation components obtained in step S950. The main controller C1 calculates corrected grids by using equation (1) or equation (5) in accordance with the X positions of AGA sample shots. The main controller C1 repeats slit drawing while performing positioning of the slit SLᵢ₊₁ in step S980 till the end of drawing of all slits in step S970.

[Method of Manufacturing Article]

A method of manufacturing an article according to an embodiment of the present invention is suitable for manufacturing a microdevice such as a semiconductor device, and an article such as an element having a microstructure. The manufacturing method includes a step of forming a latent image pattern on a photosensitive agent applied to a substrate by using the aforementioned drawing apparatus (step of performing drawing on a substrate), and a step of developing the substrate on which the latent image pattern is formed in the preceding step. Further, the manufacturing method can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application No. 2013-016134, filed Jan. 30, 2013 and Japanese Patent Application No. 2013-094636, filed Apr. 26, 2013, which are hereby incorporated by reference herein in their entirety.

What is claimed is:

1. A lithography apparatus for forming a pattern sequentially in each of a plurality of shot regions on a substrate, the apparatus comprising:
a measurement device configured to measure a position of a shot region on the substrate; and
a controller configured to control the measurement device and obtain a position of each of the plurality of shot regions based on measurement by the measurement device,
wherein the controller is configured:
to cause the measurement device to measure a position of each of a plurality of sample shot regions on the substrate, and to obtain, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions and
to cause, after forming the pattern in at least one of the plurality of shot regions, the measurement device to measure a position of each of shot regions, of the plurality of second shot regions, in a partial area on the substrate where the pattern is to be formed, and to obtain positions of shot regions in the partial area by second regression calculation based on measurement values of the positions of the shot regions in the partial area and the obtained measurement errors.

2. The apparatus according to claim 1, wherein the partial area includes a column of shot regions in which the pattern is to be formed sequentially.

3. The apparatus according to claim 1, wherein the plurality of first shot regions and the plurality of second shot regions include common shot regions.

4. The apparatus according to claim 1, wherein all the plurality of first shot regions are different from any of the plurality of second shot regions.

5. The apparatus according to claim 1, wherein the controller is configured to select the plurality of first shot regions such that a regression error of the first regression calculation falls within a tolerance.

6. The apparatus according to claim 1, wherein each of the plurality of first shot regions is a shot region outside of which another shot region is on the substrate.

7. The apparatus according to claim 1, wherein the controller is configured to correct a measurement value of a position of a shot region in the partial area based on the obtained measurement error corresponding thereto.

8. The apparatus according to claim 1, wherein the partial area includes a plurality of successive columns of shot regions, and the plurality of second shot regions include a plurality of shot regions in each of the plurality of successive columns.

9. A method of manufacturing an article, the method comprising:
forming a pattern on a substrate using a lithography apparatus; and
processing the substrate on which the pattern has been formed to manufacture the article,
wherein the lithography apparatus forms the pattern sequentially in each of a plurality of shot regions on the substrate, and includes:
a measurement device configured to measure a position of a shot region on the substrate; and
a controller configured to control the measurement device and obtain a position of each of the plurality of shot regions based on measurement by the measurement device,
wherein the controller is configured:
to cause the measurement device to measure a position of each of a plurality of sample shot regions on the substrate, and to obtain, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions and
to cause, after forming the pattern in at least one of the plurality of shot regions, the measurement device to measure a position of each of shot regions, of the plurality of second shot regions, in a partial area on the substrate where the pattern is to be formed, and to obtain positions of shot regions in the partial area by second regression calculation based on measurement values of the positions of the shot regions in the partial area and the obtained measurement errors.

10. A lithography method of forming a pattern sequentially in each of a plurality of shot regions on a substrate, the method comprising steps of:
measuring a position of each of a plurality of sample shot regions on the substrate, and obtaining, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions; and
measuring, after forming the pattern in at least one of the plurality of shot regions, a position of each of shot regions, of the plurality of second shot regions, in a partial area on the substrate where the pattern is to be formed, and obtaining positions of shot regions in the partial area by second regression calculation based on measurement values of the positions of the shot regions in the partial area and the obtained measurement errors.

11. A lithography apparatus for forming a pattern in each of a plurality of shot regions on a substrate, the apparatus comprising:
a measurement device configured to measure a position of a shot region on the substrate; and
a controller configured to control the measurement device and obtain a position of each of the plurality of shot regions based on measurement by the measurement device,
wherein the controller is configured:
to cause the measurement device to measure a position of each of a plurality of sample shot regions on the substrate, and to obtain, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions and
to cause, after forming the pattern in one partial area of the plurality of shot regions, the measurement device to measure a position of each of a plurality of shot regions with respect to another partial area of the plurality of shot regions where the pattern is to be formed, and to obtain a position of the other partial area by second regression calculation based on the measured positions with respect to the other partial area and the obtained measurement errors.

12. The apparatus according to claim 11, wherein the one partial area includes one of a plurality of partial areas obtained by dividing a column of shot regions by a dividing line parallel with a column direction, and the other partial area includes a partial area, of the plurality of partial areas, adjacent to the one of the plurality of partial areas.

13. A lithography apparatus for forming a pattern in each of a plurality of shot regions on a substrate, the apparatus comprising:
a measurement device configured to measure a position of a shot region on the substrate; and
a controller configured to control the measurement device and obtain a position of each of the plurality of shot regions based on measurement by the measurement device,
wherein the measurement device includes a first detector for obtaining measurement result at a first precision, and a second detector for obtaining measurement result at a second precision lower than the first precision,
the controller is configured:
to cause the measurement device to measure a position of each of a plurality of sample shot regions on the substrate using the first detector, and to obtain a position of each of the plurality of shot regions by first regression calculation based on a measurement value of a position of each of a plurality of first shot regions of the plurality of sample shot regions, and
to cause, before and after forming the pattern in one partial area of the plurality of shot regions, the measurement device to measure, using the second detector, a position of each of a plurality of shot regions with respect to another partial area of the plurality of shot regions where the pattern is to be formed, and to obtain a position of the other partial area by second regression calculation based on the two types of positions respectively obtained before and after forming the pattern, and a position of each of the plurality of shot regions obtained by the first regression calculation.

14. The apparatus according to claim 13, wherein the one partial area includes one of a plurality of partial areas obtained by dividing a column of shot regions by a dividing line parallel with a column direction, and the other partial area includes a partial area, of the plurality of partial areas, adjacent to the one of the plurality of partial areas.

15. The apparatus according to claim 13, wherein the second detector is arranged at each of a plurality of positions different from each other.

16. A lithography method of forming a pattern in each of a plurality of shot regions on a substrate, the method comprising steps of:
measuring a position of each of a plurality of sample shot regions on the substrate, and obtaining, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions; and
measuring, after forming the pattern in one partial area of the plurality of shot regions, a position of each of a plurality of shot regions with respect to another partial area of the plurality of shot regions where the pattern is to be formed, and obtaining a position of the other partial area by second regression calculation based on the measured positions with respect to the other partial area and the obtained measurement errors.

17. A lithography method of forming a pattern in each of a plurality of shot regions on a substrate,
wherein the method uses a first detector for obtaining a measurement result at a first precision, and a second detector for obtaining a measurement result at a second precision lower than the first precision, the method comprising steps of:
measuring a position of each of a plurality of sample shot regions on the substrate using the first detector, and obtaining a position of each of the plurality of shot regions by first regression calculation based on a measurement value of a position of each of a plurality of first shot regions of the plurality of sample shot regions; and
measuring, before and after forming the pattern in one partial area of the plurality of shot regions, using the second detector, a position of each of a plurality of shot regions with respect to another partial area of the plurality of shot regions where the pattern is to be formed, and obtaining a position of the other partial area by second regression calculation based on the two types of positions respectively obtained before and after forming the pattern, and a position of each of the plurality of shot regions obtained by the first regression calculation.

18. A method of manufacturing an article, the method comprising:
forming a pattern on a substrate using a lithography apparatus; and
processing the substrate on which the pattern has been formed to manufacture the article,
wherein the lithography apparatus forms the pattern sequentially in each of a plurality of shot regions on the substrate,
the lithography apparatus includes:
a measurement device configured to measure a position of a shot region on the substrate; and
a controller configured to control the measurement device and obtain a position of each of the plurality of shot regions based on measurement by the measurement device,
wherein the controller is configured:
to cause the measurement device to measure a position of each of a plurality of sample shot regions on the substrate, and to obtain, based on a position of each of a plurality of second shot regions, of the plurality of sample shot regions, obtained by first regression calculation based on a measurement value of a position of each of a plurality of first shot regions of the plurality of sample shot regions, and a measurement value of a position of each of the plurality of second shot regions, a measurement error with respect to each of the plurality of second shot regions and
to cause, after forming the pattern in one partial area of the plurality of shot regions, the measurement device to measure a position of each of a plurality of shot regions with respect to another partial area of the plurality of shot regions where the pattern is to be formed, and to obtain a position of the other partial area by second regression calculation based on the measured positions with respect to the other partial area and the obtained measurement errors.

19. A method of manufacturing an article, the method comprising:
forming a pattern on a substrate using a lithography apparatus; and
processing the substrate on which the pattern has been formed to manufacture the article,
wherein the lithography apparatus forms the pattern sequentially in each of a plurality of shot regions on the substrate,
the lithography apparatus includes:
a measurement device configured to measure a position of a shot region on the substrate; and
a controller configured to control the measurement device and obtain a position of each of the plurality of shot regions based on measurement by the measurement device,
wherein the measurement device includes a first detector for obtaining measurement result at a first precision, and a second detector for obtaining measurement result at a second precision lower than the first precision,
the controller is configured:
to cause the measurement device to measure a position of each of a plurality of sample shot regions on the substrate using the first detector, and to obtain a position of each of the plurality of shot regions by first regression calculation based on a measurement value of a position of each of a plurality of first shot regions of the plurality of sample shot regions, and
to cause, before and after forming the pattern in one partial area of the plurality of shot regions, the measurement device to measure, using the second detector, a position of each of a plurality of shot regions with respect to another partial area of the plurality of shot regions where the pattern is to be formed, and to obtain a position of the other partial area by second regression calculation based on the two types of positions respectively obtained before and after forming the pattern, and a position of each of the plurality of shot regions obtained by the first regression calculation.
